(19) United States
(12) Patent Application Publication
(10) Pub. No.: US 2013/0241590 A1
(43) Pub. Date: Sep. 19, 2013

(54) CONDUCTIVE FILM STRUCTURE AND CONDUCTIVE FILM TYPE PROBE DEVICE FOR ICS

(71) Applicant: INDUSTRIAL TECHNOLOGY RESEARCH INSTITUTE, Hsinchu (TW)

(72) Inventors: Min-Chieh CHOU, Taipei City (TW); Tune-Hune KAO, Hsinchu City (TW); Jen-Hui TSAI, Hsinchu City (TW)

(73) Assignee: INDUSTRIAL TECHNOLOGY RESEARCH INSTITUTE, Hsinchu (TW)

(21) Appl. No.: 13/887,091

(22) Filed: May 3, 2013

Related U.S. Application Data
(62) Division of application No. 12/426,695, filed on Apr. 20, 2009.

(30) Foreign Application Priority Data
Dec. 29, 2008 (TW) 097151197

(51) Int. Cl. G01R 31/28; G01R 1/073

(52) U.S. Cl. CPC G01R 31/2886; G01R 1/073
USPC 324/756.03; 174/251

(57) ABSTRACT

A method for forming a conductive film structure is provided, which includes: providing an insulating substrate having a surface; forming a plurality of trenches in the surface of the insulating substrate, wherein the trenches are extended substantially parallel to each other; disposing the insulating substrate into a plating solution and plating conducting layers within the trenches to form a plurality of micro-wires; and stacking a plurality of the insulating substrates or winding or folding the insulating substrate along an axis substantially parallel to an extended direction of the micro-wires to form a conducting lump.

### CROSS REFERENCE TO RELATED APPLICATIONS

This application is a Divisional of pending U.S. patent application Ser. No. 12/426,695, filed on Apr. 20, 2009 and entitled “Conductive film structure, fabrication method thereof, and conductive film type probe device for ICs”, which claims priority of Taiwan Patent Application No. 097151197, filed on Dec. 29, 2008, the entirety of which is incorporated by reference herein.

### TECHNICAL FIELD

The technical field relates to a conductive film structure and a fabrication method thereof, and in particular relates to a conductive film structure suitable for fabricating a probe card.

### BACKGROUND

Probe cards are used to perform electrical testing of integrated circuits (ICs) on a wafer before they are cut and packaged. Thus, allowing for determination of faulty ICs before further processing. With the development of nanoelectronic technology, line widths of ICs have shrunk to nano scale and the spacings between pads have also shrunk. Thus, probe cards with small probe pin pitches are required to accommodate the ICs with decreased spacings between pads.

According to the International Technology Roadmap for Semiconductor (ITRS), the smallest line width of an IC is currently 68 nanometers and the spacings between pads for testing is 30 μm. The ITRS expects the line width of an IC to further shrink to 36 nanometers and the spacings between pads for testing to be further shrunk to 20 μm. However, currently, a serious technical bottleneck has been reached, for conventional probe cards to perform electrical testing of ICs on a wafer with pad spacings smaller than 30 μm.

Conventional probe cards which are commercially available comprise a cantilever type probe card, such as an epoxy ring probe card, a vertical type probe card, such as a Cobra probe card, and advanced MEMS probe cards commonly used for DRAMs.

Although the probe pin pitches of the cantilever type probe card may be as small as 40 μm, the cantilever type probe card is only suitable for testing pads disposed around a periphery of a wafer to be tested. Pads inside of the wafer can not be tested and the number of the probe pins is also limited. As for the vertical type probe cards, such as that described in U.S. Pat. No. 4,027,935 titled “Contact for an electrical contactor assembly”, although the pads inside of the wafer can be tested and the number of probe pins is relatively less limited, there is a technical bottleneck for the probe pin pitches to be smaller than 100 μm. In addition, the vertical type probe card is only suitable for testing of flip chip packaged ICs.

Additionally, each probe pin of both the cantilever type and vertical type probe cards must be manually installed in a printed circuit board. As such, the manufacturing cost depends highly on the amount of probe pins. As requirement for probe pins increase, so does the manufacturing cost.

As for MEMS probe cards commonly used for DRAMs, such as that described in U.S. Pat. No. 5,476,211 titled “Method of manufacturing electrical contacts, using a sacrificial member” or U.S. Pat. No. 6,268,015 titled “Method of making and using lithographic contact springs”, the manufacturing process is very complicated. Specifically, fabrication complexity increases for probe pin pitches smaller than 70 μm. In addition, testing pad arrangements are limited. As such, relative costs for MEMS probe cards are high.

Additionally, conventional probe cards are all limited to “one probe corresponding to one pad” type. When disposition of testing pads are adjusted, probe pins need to be re-fabricated. Further, the fabrication of probe cards is hindered by the process limitations of micron probe pins. Probe pin manufacturing costs using conventional fabrication methods, such as molding, drawing, or rolling, are not feasible. In addition, the configuration and size of probe pins are limited by many factors. Although a photolithography/etching method, such as that described in Taiwan Patent Application No. 90107441 and 93107026, may be used to fabricate probe pins, they still use the “one probe corresponding to one pad” type. Therefore, probe cards, with small probe pin pitches to accommodate ICs with decreased spacings between pads and fabricated with relatively lower costs is desired to accommodate testing requirements of nanoelectronic devices.

Thus, in lieu of the above, a novel conductive film structure, manufacturing method thereof, and a probe card having the conductive film structure has already been disclosed by the inventor. Taiwan Patent Application No. 96137385 and U.S. patent application Ser. No. 12/032,169 are incorporated by references herein. For this method, a single-layered conductive film is first formed overlying a substrate. The single-layered conductive film comprises an insulating film and micro-wires formed therein. Then, the single-layered conductive film is removed from the substrate and stacked with other single-layered conductive films, formed and removed by the same method, to form a conductive film structure. The micro-wires in the conductive film structure can be used as the probe pins in probe cards. By using a photolithography and etching process, diameters and pitches of probe pins can be easily controlled, overcoming conventional probe pin fabricating difficulties, such as limitation for low pin counts, having to manually process each pin, limitation of pin arrangements, and problems with further shrinking pin diameters. Additionally, because the conductive film type probe card of the disclosure is not a “one probe corresponding to one pad” type probe card, it overcomes the technical bottleneck of probe pin pitches and probe pin counts for conventional probe cards and has greater application potential. However, the method mentioned above requires repeatedly forming and removing a plurality of single-layered conductive films. Additionally, the single-layered conductive films need to be individually adhered one by one, thus, taking up time and effort.

Thus, in order to reduce process work time and manufacturing difficulty of the conductive film type probe card, a novel conductive film structure, manufacturing method thereof, and a probe card having the conductive film structure has also been disclosed by the inventor. Taiwan Patent Application No. 97117542 and U.S. patent application Ser. No. 12/323,422 are incorporated by references herein. For this method, a conductive film structure is formed by winding or folding a single-layered conducting film, thus reducing process time and costs. However, during the process of applying adhesive on the single-layered conducting film, micro-wires of the single-layered conducting film may be removed or damaged, causing product defects.

Thus, providing a novel conductive film structure, manufacturing method thereof, and a probe card having the conductive film structure without the problems mentioned above, is desired.

### SUMMARY

In accordance with an embodiment of the disclosure, a conductive film structure is provided, comprising: an insulating bulk having a first surface and an opposite second surface; at least a bonding interface located in the insulating bulk and extending from the first surface to the second surface; and a plurality of micro-wires located in the insulating bulk, wherein extended directions of the micro-wires are substantially parallel to a normal vector of the first surface or the second surface, the micro-wires are disposed substantially along the bonding interface, and a surface of each of the micro-wires is coplanar with the bonding surface.

In accordance with another embodiment of the disclosure, a conductive film type probe device for ICs is provided, comprising: a circuit board having a plurality of first contacts and a plurality of second contacts, wherein the first contacts are used to electrically connect to a testing apparatus; and a conductive film structure as described in the embodiments of the disclosure mentioned above, wherein the each of the second contacts electrically connects to at least one of the micro-wires of the conductive film structure.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1A-1E are cross-sectional views showing the step of forming a conductive film structure in accordance with an embodiment of the disclosure;

FIG. 2A is a three dimensional top view showing the insulating substrate shown in FIG. 1A;

FIG. 2B is a top view showing an insulating substrate in accordance with another embodiment of the disclosure;

FIG. 2C is a three dimensional top view of the structure shown in FIG. 1B;

FIG. 2D is a cross-sectional view showing an insulating substrate and micro-wires in accordance with an embodiment of the disclosure;

FIG. 3 is a cross-sectional view showing a conductive film type probe device for ICs in accordance with an embodiment of the disclosure;

FIG. 4 shows the process of forming a conducting lump by using a winding core in accordance with an embodiment of the disclosure;

FIG. 5 shows a conducting lump formed by folding in accordance with an embodiment of the disclosure;

FIG. 6 shows forming a conducting lump by a continuous winding process in accordance with an embodiment of the disclosure; and

FIG. 7 is a cross-sectional view showing a conductive film structure of stacked type in accordance with an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In embodiments of the disclosure, a conductive film structure, fabrication method thereof, and a conductive film type probe device for ICs are provided.

A conductive film structure of one embodiment of the disclosure is formed by forming a plurality of trenches substantially parallel to each other which are formed in the surface of the insulating substrate. The trenches are further filled with conducting materials to form a single-layered conducting film. Through stacking, winding, or folding the single-layered conducting film, a conductive film structure of a conducting lump type is thus formed. The conductive film structure may be used as a component of an IC detecting device, such as a probe device or a probe card.

The embodiments of the disclosure are illustrated in detail below in accordance with the accompany drawings. Throughout the various views and illustrative embodiments of the disclosure, like reference numbers are used to designate like elements. The shape of each element or layer is not limited to the specific type in the drawings. Although the embodiments of the disclosure may mainly be applied to IC probe devices, the conductive film structure may be adapted to other applications.

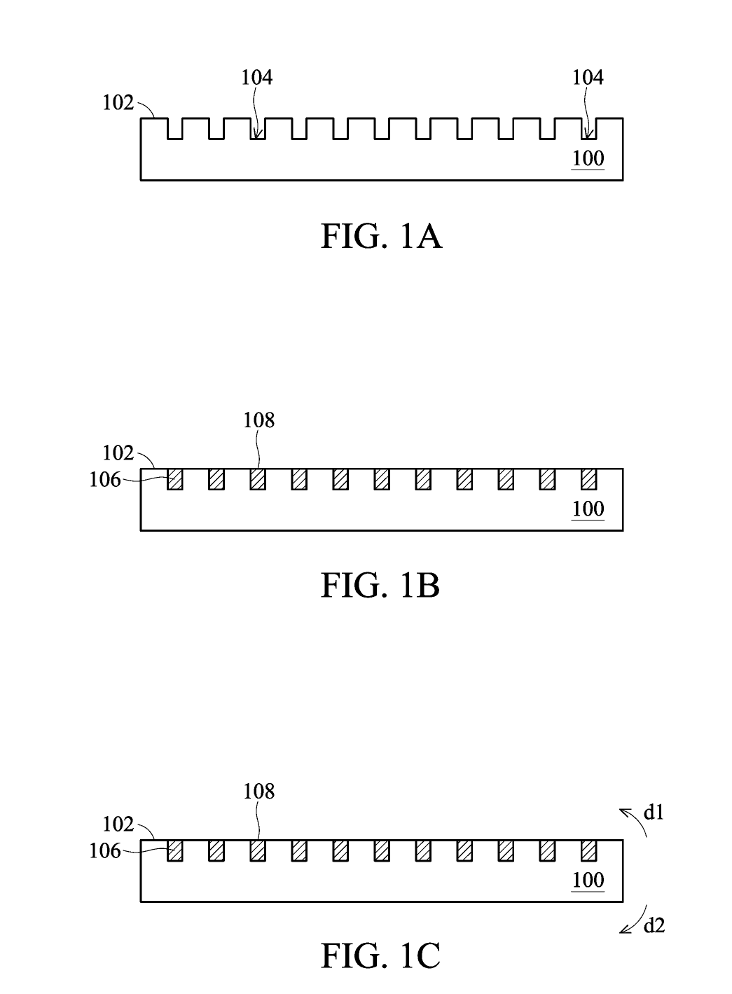

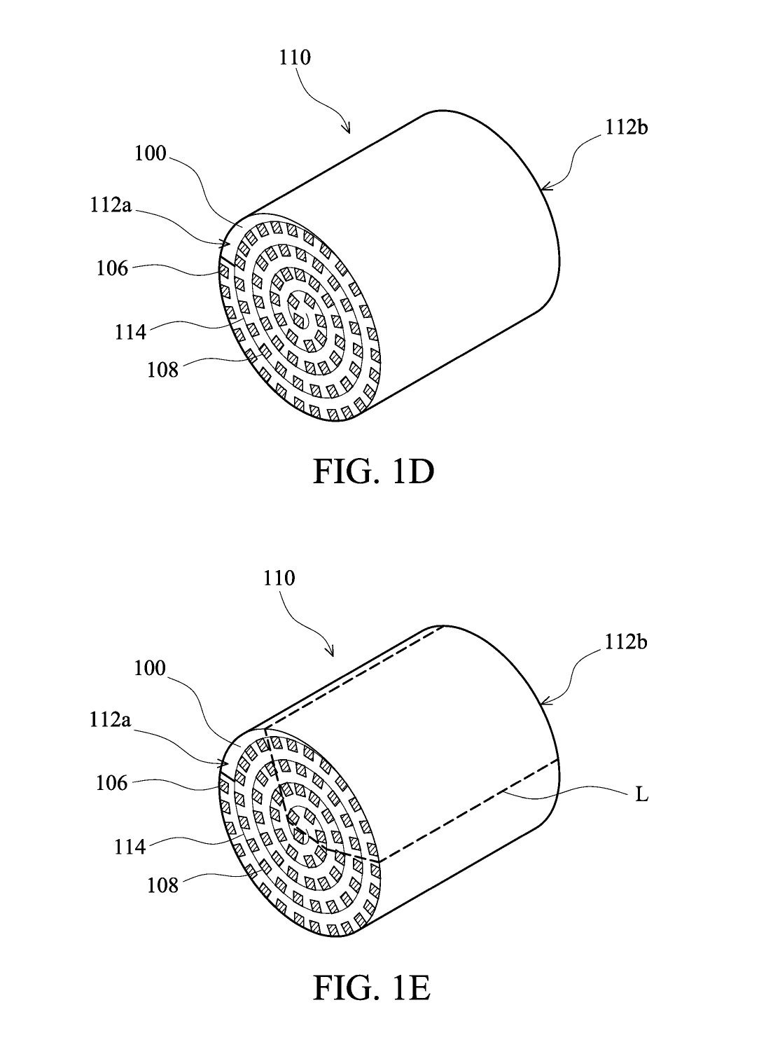

FIGS. 1A to 1E are cross-sectional views showing the steps for fabricating a conductive film structure according to one embodiment of the disclosure. As shown in FIG. 1A, an insulating substrate 100 is first provided. The insulating substrate 100 may comprise any kind of insulating material. In one embodiment, the insulating substrate 100 may comprise a polymer, such as polydimethylsiloxane (PDMS), polyimide (PI), polyethylene terephalate (PET), polyurethane (PU), polycarbonate (PC), derivatives thereof, the like thereof, or combinations thereof. The insulating substrate 100 is preferably an insulating material with good elasticity. After completing fabrication of the conductive film structure, a material with elasticity can be used to absorb the impact force transmitted to micro-wires in the conductive film structure when contacting with testing pads, thus, improving the reliability and impact resistance of the conductive film structure. In one embodiment, the thickness of the insulating substrate 100 may be about 5 to 20 μm, or preferably about 7 to 15 μm. However, the thickness of the insulating substrate 100 may be adjusted according to requirement.

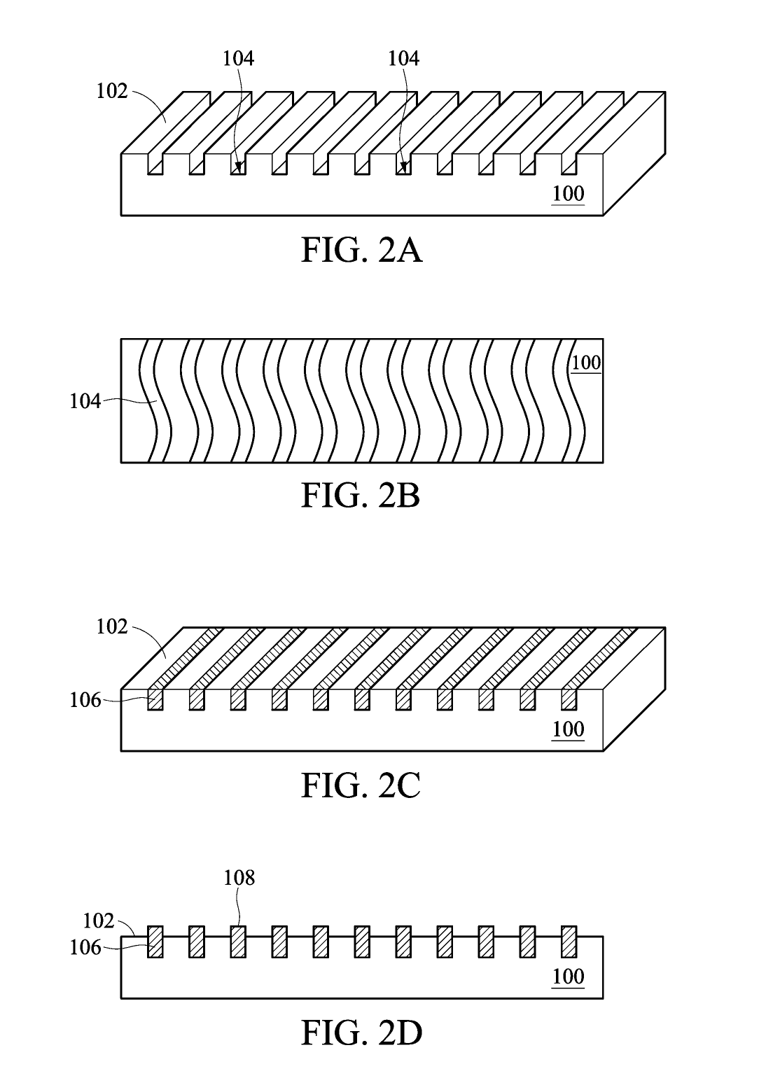

Still referring to FIG. 1A, a plurality of trenches 104 are formed from a surface 102 of the insulating substrate 100. The trenches 104 are extended substantially parallel to each other. That is, long axes of the trenches 104 are substantially parallel to each other. FIG. 2A shows a three dimensional top view of the insulating substrate shown in FIG. 1A. As shown in FIG. 2A, long axis directions or extended directions of the trenches 104 are substantially parallel to each other. In one embodiment, spacings between the trenches are all the same. For example, the spacings may all be about 5 μm or even smaller, such as about 1 to 3 μm. In one embodiment, a cross area of the trench 104 may be square-shaped and have a width of about 5 μm. However, the cross area of the trench 104 is not limited to being square-shaped. In another embodiment, the cross area of the trench 104 may have any suitable shape, such as shapes including a square, rectangle, half-circle, half-ellipse, trapezium, or polygon shape. A characteristic width of the cross area is, for example, about 1 to 10 μm, wherein the characteristic width means a width for a shape of a square, rectangle, or trapezium, a diameter for a shape of a half-circle or half-ellipse, or a maximum width for a shape of a polygon. In one embodiment, spacings between the trenches 104 are all the same. In other embodiments, the spacings between the trenches 104 are all different or partially the same.

Although the trenches shown in FIG. 2A are straight lines having long axis directions or extended directions substantially parallel to each other, the trenches of the embodiment of the disclosure are not limited to this type. For example, FIG. 2B shows a top view of an insulating substrate 100 according to another embodiment of the disclosure. The trenches 104 are not in straight lines but have many inflections while the long axis direction or extended direction of each micro-wire is still parallel to each other. FIG. 2A or 2B illustrates exemplary insulating substrates of embodiments of the disclosure. Any insulating substrate, which has linking lines between two opposite ends of each trenches which are substantially parallel to each other, is within the scope of the embodiments of the disclosure. From the following description, it should be understood that each trench 104 will be filled with a conducting layer to form a plurality of micro-wires. Two opposite ends of each micro-wire will serve as electrical contact points with other conducting structures, such as with pads of ICs to be tested at the one end and with a circuit board of a testing apparatus at the other end. Depending on what type of micro-wires are desired, cross areas, spacings therebetween, disposition, extended directions, and so on, of the respective trenches of the micro-wires may be formed accordingly.

The forming of the trenches 104 comprises removing portions of the insulating substrate 100 from the surface 102 by an energy beam. After the insulating substrate 100 is patterned by the energy beam, the removed portions of the insulating substrate 100 form the trenches of an embodiment of the disclosure. Specific portions of the insulating substrate 100 are removed according to the desired type of the trenches. A suitable energy beam may include, for example, a laser beam, an ion beam, an electron beam, a plasma, or combinations thereof. The exposure energy and time of the energy beam may be adjusted according to requirement. In one embodiment, it is preferable to form trenches having roughened sidewalls. Trenches having roughened sidewalls are suitable for forming conducting layers therein. Compared with the disclosure (TW Pat. No. 97117542) disclosed by the present inventor of the application in which an energy beam is used to pattern a conducting layer, the energy beam used for patterning the insulating substrate 100 in the embodiment of the disclosure requires less exposure energy and process time. Particularly, when the material of the insulating substrate is polymer, the energy beam is capable of patterning the polymer insulating substrate more easily and efficiently, compared with patterning a metal conducting layer.

As shown in FIG. 1B, the insulating substrate 100 with the trenches 104 is disposed into a plating solution. Conducting layers (or conducting material) are plated within the trenches 104 to form a plurality of micro-wires 106. The material of the conducting layer (or micro-wires 106) may include, for example, copper, nickel, cobalt, gold, tin, silver, lead, or alloys thereof. Suitable alloys may include, for example, nickel-cobalt alloy, nickel-tin alloy, tin-cobalt alloy, nickel phosphorus, tin-silver alloy, or tin-lead alloy, and so on. As shown in FIG. 2C, the long axis directions or extended directions of the micro-wires 106 are substantially parallel to each other.

In one embodiment, before disposing the insulating substrate 100 into the plating solution, the insulating substrate 100 is disposed into an active agent solution to form active metal particles overlying the sidewalls of the trenches 104. Before disposing the insulating substrate 100 into the active agent solution to form the active metal particles, the insulating substrate 100 having the trenches 104 is preferably to be treated with some subsequent processes including acid washing, water washing, and drying. Then, the insulating substrate 100 may be disposed into the active agent solution. One of the reasons to form the active metal particles is the plating of the conducting layers (or conducting materials) to adhere on the active metal particles on the sidewalls of the trenches 104 may be benefited when disposing the insulating substrate 100 into the plating solution in following process.

In one embodiment, the trenches 104 are formed from a surface of a polyimide insulating substrate by using a pulse excimer laser. The surfaces of the sidewalls of the trenches 104 irradiated by the laser beam are rough. For example, the pulse laser beam may have a wavelength of about 248 nm, an energy density of about 0.54 J/cm², a pulse time interval of about 50 nanoseconds, a repetition frequency of about 40 Hz, and a number of pulses of about 30 to 180. When the insulating substrate 100 is then disposed into the active agent solution, the active metal particles only precipitate on the rough surface of the trenches 104. The active metal particles substantially do not precipitate on the upper surface 102 of the insulating substrate 100. Suitable active agent solutions may include metal ions, such as palladium ions, platinum ions, tin ions, gold ions, silver ions, nickel ions, or combinations thereof, such as combination of palladium ions and nickel ions. In some embodiments, the active agent solution may include 0.1˜0.3 g/L of PdCl₂, 0.1˜0.3 g/L of PtCl₂, 20˜40 g/L of SnCl₂, 0.5˜1 g/L of AuCl₃, and 0.5˜5 g/L of AgNO₃. The precipitated active metal particles adhered on the surfaces of the trenches 104 may include, for example, palladium, platinum, tin, gold, silver, nickel, or alloys thereof, such as nickel-palladium alloy.

In one embodiment, an insulating substrate 100 having a plurality of trenches 104 is disposed into a first active agent solution containing 20 g/L of tin chloride dihydrate and 0.09 mole/L of hydrochloric acid for about 5 to 10 minutes. Then, the insulating substrate 100 is disposed into a second active agent solution containing 0.3 g/L of palladium chloride and 0.027 mole/L of hydrochloric acid for about 5 to 10 minutes. Then, the insulating substrate 100, having active metal particles formed on the surfaces of the sidewalls and the bottom portions of the trenches 104, is disposed into a plating solution. In this embodiment, the plating solution may include an electroless plating solution, such as an electroless copper plating solution, electroless nickel plating solution, electroless gold plating solution, or combinations thereof. By using the electroless plating solution, conducting layers 106 (or conducting materials) may selectively be formed only on the surfaces of the trenches with active metal particles formed thereon, and not on the surface 102 of the insulating substrate 100. The surface 102 is relatively smooth and thus has substantially no active metal particles adhered thereon. When the insulating substrate 100 is disposed into the plating solution for forming the conducting layers, the conducting layers are only plated within the trenches 104. There is substantially no conducting layer formed on the surface 102. The conducting layers in the trenches may be electrically isolated from each other naturally. Additional patterning processes are not needed to form the plurality of micro-wires 106 (conducting layers in the trenches 104) extending substantially parallel to each other. In one embodiment, the electroless plating solution includes, for example, 14 g/L of copper sulfate, 4 g/L of tartaric acid, 15.5 g/L of potassium sodium tartrate, 0.1827 mole/L of formaldehyde, 10 g/L of sodium hydroxide, and 4.2 g/L of sodium carbonate. The electroless plating solution may have a pH value of about 12 and is reacted for about 10 minutes. By using the plating process, the plurality of micro-wires 106 extending substantially parallel to each other may be formed in the insulating substrate 100.

In addition, in one embodiment, the heights of the micro-wires 106 may be adjusted by tuning the composition, concentration, and/or temperature of the plating solution as well as the disposing time of the insulating substrate 100 in the plating solution. In another embodiment, thin conducting layers may be first formed on the surfaces of the sidewalls and bottom portions of the trenches 104. Then, an electroplating process may be performed to fill conducting layers into only the trenches 104, thus forming the plurality of micro-wires 106 extending substantially parallel to each other.

In the embodiment shown in FIG. 1B, the heights of the micro-wires 106 are controlled so that the surfaces 108 of the micro-wires 106 are substantially coplanar with the surface 102 of the insulating substrate 100. In another embodiment, the insulating substrate 100 may be disposed in the plating solution for a longer time so that at least portions the surfaces 108 of the micro-wires 106 may be higher than the surface 102 of the insulating substrate 100. FIG. 2D shows a cross-sectional view of an embodiment, wherein at least portions of the micro-wires 106 are higher than the surface 102. Note that for both embodiments shown in FIG. 1B and 2D, the micro-wires 106 are at least partially or completely underlying the surface 102 of the insulating substrate 100, thus being protected by the insulating substrate 100. The problem, which may be encountered in the previous disclosure of the present inventor (TW Pat. No. 97117542), wherein the micro-wires 106 may be damaged or removed in the following processes due to rubbing is prevented.

After forming the plurality of micro-wires 106, a conducting lump may be formed by stacking a plurality of the insulating substrates 100 or winding or folding the insulating substrate 100 along an axis substantially parallel to the extended direction of the micro-wires. Directly or after being cut, the conducting lump may be used as a component of a conductive film type probe device for IC, capable of replacing conventional probe cards.

First, referring to FIG. 1C, the winding of the insulating substrate according to an embodiment of the disclosure is discussed. As shown in FIG. 1C, the insulating substrate 100 is directly wound along an axis substantially parallel to an extended direction (or long axis direction) of the micro-wires 106 to form a conducting lump. The insulating substrate 100 may be wound with a direction d1 or direction d2. In one embodiment, the insulating substrate 100 is directly wound with the direction d1. In this case, the material of the insulating substrate 100 is preferably flexible polymer. It is preferable to apply adhesive (not shown) on the insulating substrate 100 and/or the micro-wires 106, which may help to fix the conducting lump during the winding process. Alternatively, the insulating substrate 100 may be an adhesive polymer substrate so that the conducting lump may be fixed directly during the winding process. In another embodiment, the insulating substrate 100 is directly wound with a direction d2. In this case, it is preferable to apply an adhesive overlying the bottom of the insulating substrate 100 to fix the wound conducting lump. Similarly, an adhesive polymer substrate may be used when winding with the direction d2.

FIG. 1D illustrates a cylindrical conducting lump 110 formed by a direct winding process for a conductive film structure of one embodiment of the disclosure. In the embodiment shown in FIG. 1D, the conductive film structure is formed by winding the insulating substrate 100 with the direction d2. Thus, the outmost surface of the wound conductive film structure includes some micro-wires 106. If the insulating substrate 100 is wound with the direction d1, the outmost surface of the wound conductive film structure does not include any micro-wires 106. In this case, the outmost surface of the wound conductive film structure is a surface opposite to the surface 102 and includes no micro-wires.

Referring to FIG. 1D, the conducting lump 110 (conductive film structure) comprises an insulating bulk 100, which is constructed by the wound insulating substrate 100, having a first surface 112a and an opposite second surface 112b. The conducting lump further comprises a bonding interface 114 located in the conducting lump 110 and extending from the first surface 112a to the second surface 112b. In this embodiment, the bonding interface 114 is a spiroid interface. The conducting lump 110 further comprises a plurality of micro-wires 106, wherein the extended directions (or long axis directions) of the micro-wires 106 are substantially parallel to a normal vector of the first surface 112a or the second surface 112b, wherein the micro-wires 106 are disposed substantially along the bonding interface 114, and wherein the surfaces 108 of the micro-wires 106 are coplanar with the bonding layers 114.

In addition, a similar winding process may be performed to wind the insulating substrate 100 shown in FIG. 2D. An additional insulating layer overlying the insulating substrate 100 and the micro-wires 106 is formed first. Then, a conductive film structure according to an embodiment of the disclosure can be formed by a similar winding process. The main structural difference between the conductive film structure shown in FIG. 1D and the conductive film structure formed in this embodiment is the relationship between the surfaces 108 of the micro-wires 106 and the bonding interfaces 114. Referring to FIG. 1B, because the surfaces 108 of the micro-wires 106 are substantially coplanar with the surface 102 of the insulating substrate 100, the surfaces 108 of the micro-wires 106 of the wound conducting lump 100 are coplanar with the bonding interface 114. However, when the structure wound is that shown in FIG. 2D, the interface of the wound conducting lump will not be coplanar with the surfaces 108 of the micro-wires 106 because the surfaces 108 of the micro-wires are not coplanar with the upper surface of the additional insulating layer.

In one embodiment, after forming the conducting lump 110, a conducting material, such as copper, gold, silver, or alloys thereof may be deposited overlying two opposite ends of the micro-wires 106 by, for example, electrochemical deposition to elongate the micro-wires 106 such that the opposite ends thereof are exposed or protruding from the first surface 112a and/or the second surface 112b of the conducting lump 110. In another embodiment, after forming the conducting lump 110, a portion of the insulating substrate 100 may be removed by using, for example, a laser beam or other suitable methods such that at least one end of the micro-wires 106 protrudes from the conducting lump 110. The exposed or protruding micro-wires 106 may facilitate the contact and electrical path between the conducting lump 110 and other devices, such as pads of a to-be-tested wafer.

Besides the conductive film structure of the conducting lump 110 illustrated in FIG. 1D, in other embodiments of the disclosure, the conductive film structures also comprise smaller conducting lumps cut from the conducting lump 110 shown in FIG. 1D. For example, the conducting lump 110 may be cut along the dashed line L shown in FIG. 1E to obtain a smaller conducting lump. However, the cutting region is not limited to that shown in FIG. 1E.

The conductive film structure of the disclosure comprises the conducting lump 110 shown in FIG. 1D or the smaller conducting lump, as illustrated in FIG. 1E, cut from the conducting lump 110. The conductive film structures mentioned above may be used as a component of a conductive film type probe device for ICs.

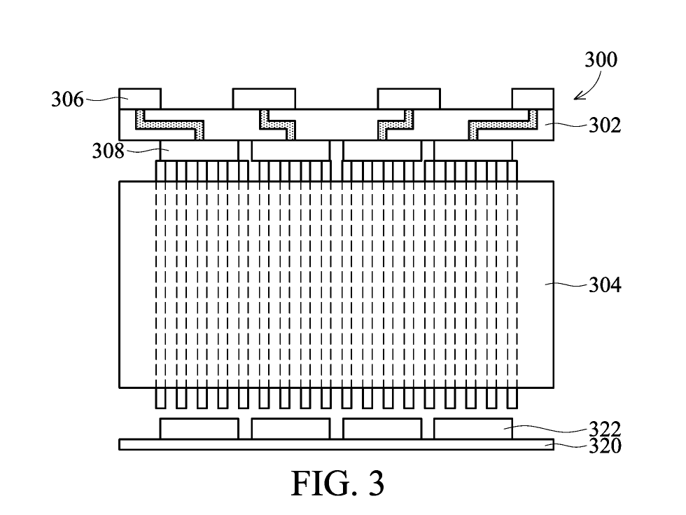

FIG. 3 shows a cross-sectional view of a conductive film type probe device for ICs in accordance with an embodiment of the disclosure. The conductive film type probe device for IC 300 comprises a circuit board 302 and a conductive film structure 304. The circuit board 302 has a plurality of first contacts 306 and a plurality of second contacts 308 disposed overlying opposite sides of the circuit board 302, respectively. The first contacts 306 are used to electrically connect to a testing apparatus while the second contacts 308 are used to electrically connect to the micro-wires of the conductive film structure 304. The conductive film structure 304 may be linked to the circuit board 302 by an adhesive or any physical locking design to make each of the second contacts 308 electrically connected to at least one of the micro-wires of the conductive film structure 304.

As shown in FIG. 3, each second contact 308 electrically connects to a plurality of different micro-wires. However, each second contact 308 is not limited to electrically connecting to a plurality of different micro-wires. Alternatively, in another embodiment, each second contact 308 only electrically connects to one different micro-wire. In yet another embodiment, a portion of the second contacts 308 only electrically connect to one different micro-wire while another portion of the second contacts 308 electrically connect to a plurality of different micro-wires, respectively. FIG. 3 further shows a wafer 320 which is to be tested, having ICs to be tested therein and having a plurality of contacts 322. In one embodiment, the second contacts 308 are arranged corresponding to, and in the same manner as the contacts of the IC of the wafer 320 to be tested. The testing apparatus may move the conductive film type probe device for IC 300 to make the micro-wires electrically connect to the pads 322. Electrical information of the IC to be tested may be transmitted to the testing apparatus for reading from the electrical connection between the pads 322 and the micro-wires.

The conductive film type probe device for IC 300 of an embodiment of the disclosure differs from the conventional probe cards with “one probe corresponding to one pad” type. In one embodiment, one single pad 322 may contact with a plurality of probes (micro-wires). In addition, spacing or pitches between probes (spacing between micro-wires) and cross-sections of probes (shapes or cross-sectional areas of micro-wires) may be modified according to methods of the embodiments of the disclosure to accommodate different testing situations. In one embodiment, the conducting lump 110 illustrated in FIG. 1E may be directly used as the conductive film structure 304 of the conductive film type probe device for the IC 300. The first surface 112a or the second surface 112b may exactly fit with the area and shape of the wafer 320 to be tested. Thus, devices of the entire wafer 320 to be tested may be detected in one testing process. In one embodiment, the layout information of the contacts 322 of the wafer 320 to be tested may be first inputted to the testing apparatus. Thus, each probe (micro-wire) and its contacting pad connected to a corresponding device may be firstly addressed or identified. That is, each probe, and which pad an individual probe electrically connects to, may be firstly identified. Therefore, electrical information of all devices in the entire wafer to be tested may be obtained in a single test.

The conductive film structure of embodiments of the disclosure may be formed, as shown in FIGS. 1A-1E, by directly winding the structure, such as that illustrated in FIGS. 1B or 2D. However, in another embodiment, another fabrication method may be applied. For example, the conductive film structure may also be formed by winding the insulating substrate around a winding core. Alternatively, the conductive film structure may not be formed by winding but by folding instead. In the following description, other possible methods to form the conductive film structure according to embodiments of the disclosure will be illustrated in more detail.

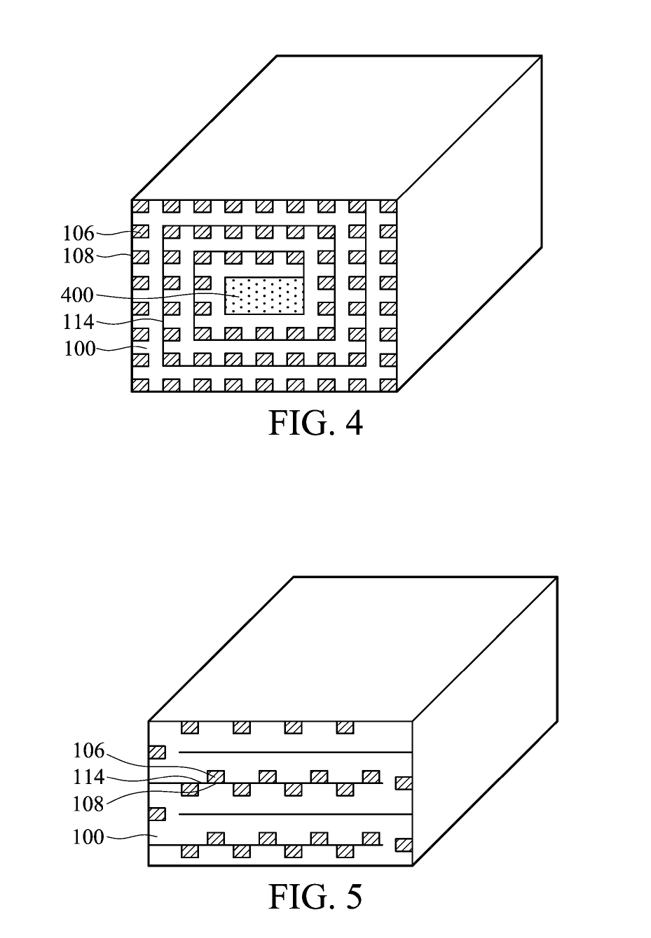

Referring to FIG. 4, a conductive film structure or conducting lump of an embodiment is formed by winding a structure such as that shown in FIG. 1C around a winding core 400. The winding core 400 is substantially a pillar structure. The cross-section of the pillar structure may be any suitable shape, such as a square, rectangle, circle, ellipse, trapezium, or triangle shape and so on. By rotating the winding core 400, the winding of the structure shown in FIG. 1C may be initiated, and thus a conducting lump may be formed. If winding cores with different cross-section shapes are used, types of the bonding interface 114 may be accordingly different. In addition, a cutting process similar to the cutting process shown in FIG. 1E may be performed to obtain a smaller conducting lump serving as a conductive film structure. The conductive film structure may be used by the conductive film type probe device for ICs shown in FIG. 3. In this embodiment, the surfaces 108 of the micro-wires 106 are coplanar with the bonding interface 114. In another embodiment, the surfaces 108 of the micro-wires 106 are completely not or partially not coplanar with the bonding interface 114.

The conductive film structure may be formed not only by direct winding or winding around a winding core, but also by folding. FIG. 5 shows a conductive film structure formed by folding according to an embodiment of the disclosure. The conductive film structure or conducting lump shown in FIG. 5 is formed by folding the structure shown in FIG. 1C, for example. The folded conductive film structure (or conducting lump) is similar to the structure shown in FIG. 1D or FIG. 4, however, the bonding interface 114 of the folded conductive film is not a spiroid interface but a folding bonding interface 114 instead. Similarly, a cutting process similar to that illustrated in FIG. 1E may be performed to obtain a smaller conductive film structure (or conducting lump), which may be used in the conductive film type probe device for ICs shown in FIG. 3. It should be appreciated that when a folding process is applied to form the conductive film structure (or conducting lump), it is preferable to adjust the spacings between the micro-wires 106 to prevent shorting to occur between some of the micro-wires during the folding process. The spacings between the micro-wires 106 may be adjusted when patterning the insulating substrate 100 to form the trenches 104. In this embodiment, the surfaces 108 of the micro-wires 106 are coplanar with the bonding interface 114. In another embodiment, the surfaces 108 of the micro-wires 106 are completely not or partially not coplanar with the bonding interface 114.

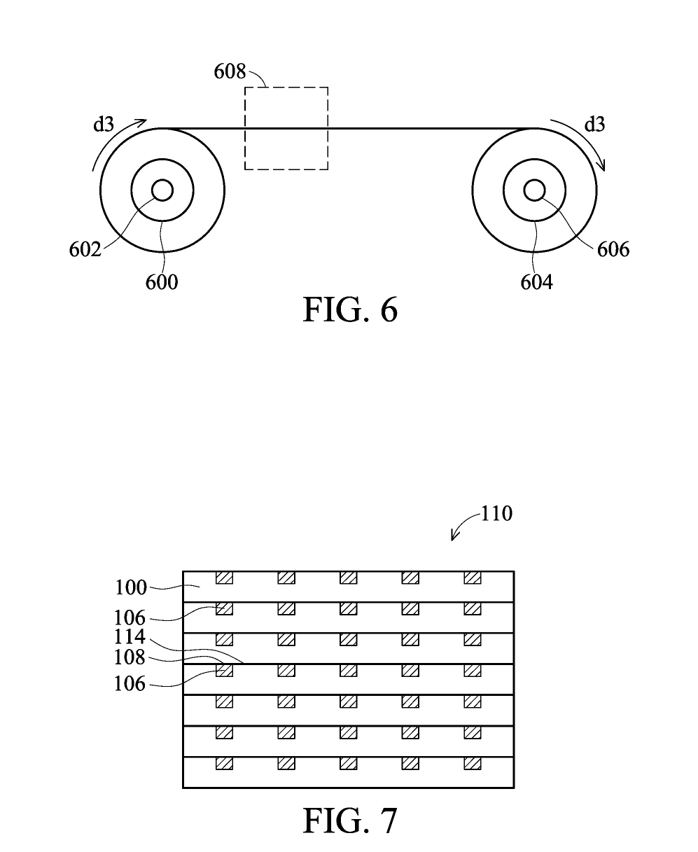

The fabrication of the conductive film structure of embodiments of the disclosure may be simultaneously formed by a roll-to-roll process (or continuous winding process), which is capable of fabricating a large number of conductive film structures in a relatively short process time. FIG. 6 shows the fabrication of the conductive film structure using a roll-to-roll process (or continuous winding process) in accordance with an embodiment of the disclosure. First, the structure shown in FIG. 1B is wound into a cylindrical structure around a first roller 600 and the other end of the structure is disposed around a second roller 604. Then, the first roller 600 and the second roller 604 are rotated around the rotating axes 602 and 606 with, for example, a direction d3. Meanwhile, depending on design, an adhesive applying element 608 may be used to apply adhesive overlying the insulating substrate 100 and the micro-wires 106. Thus, a conductive film structure or a conducting lump 110 may be formed and collected through the winding of the second roller 604. In one embodiment, the conductive film structure or the conducting lump 110 obtained may directly be used as the conducting structure of the conductive film type probe device for ICs. Alternatively, a smaller conducting lump may be cut from the conducting lump 110 and be used for desired applications.

The conductive film structure may be formed not only by winding or folding, but also by stacking a plurality of single conductive layer. FIG. 7 shows a conductive film structure of stacking type according to an embodiment of the disclosure. The conductive film structure or conducting lump shown in FIG. 7 is formed by stacking a plurality of structures as shown in FIG. 1B, for example. Adhesive may be applied between the interfaces between the insulating substrates 100 to fix and form the conducting lump 110. Alternatively, an adhesive insulating substrate 100 may be used, thus application of the adhesive may be omitted. The conductive film structure (or conducting lump 110) shown in FIG. 7 comprises an insulating bulk constructed by the stacked insulating substrates 100, a plurality of bonding interfaces 114, and a plurality of micro-wires 106. The bonding interfaces 114 comprise a plurality of planes parallel to each other. That is, the conducting lump 110 shown in FIG. 7 comprises a plurality of interfaces 114 parallel to each other. The long axis directions or extended directions of the micro-wires 106 are substantially parallel to each other and disposed along the bonding interfaces 114. In addition, a cutting process similar to that illustrated in FIG. 1E may be performed to obtain a smaller conductive film structure (or conducting lump), which may be used in the conductive film type probe device for ICs shown in FIG. 3. In this embodiment, the surfaces 108 of the micro-wires 106 are coplanar with the bonding interface 114. In another embodiment, the surfaces 108 of the micro-wires 106 are completely not or partially not coplanar with the bonding interface 114.

The embodiments of the disclosure have many advantageous features. In addition to all of the advantageous features similar to the previous TW patent application and U.S. patent application of the inventor as mentioned above, the embodiments of the disclosure further comprise an additional important advantageous feature, wherein the problem of the micro-wires being damaged or removed during the fabricating process due to rubbing is prevented. The spacing between probes (spacing between micro-wires or probe pin pitch), cross-sections of probes (shapes or cross-sectional areas of micro-wires), and the disposition of the probes are modified according to methods of the embodiments of the disclosure to accommodate different testing situations. The conductive film structure or the conductive film type probe device for ICs of the embodiments of the disclosure may replace conventional probe cards due to their simplified, faster, and lower cost manufacturing process, and ability to accommodate ICs with decreased spacing between pads, thus meeting nano scale technology trend requirements. In addition, the conductive film structures of the embodiments of the disclosure are not limited to the application in probe devices for ICs. In contrast, the conductive film structure of the embodiments of the disclosure may be used in many other applications, such as a microelectronic conducting element and so on.

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. A conductive film structure, comprising:
an insulating bulk having a first surface and an opposite second surface;
at least a bonding interface located in the insulating bulk and extending from the first surface to the second surface; and
a plurality of micro-wires located in the insulating bulk,
wherein extended directions of the micro-wires are substantially parallel to a normal vector of the first surface or the second surface,
the micro-wires are disposed substantially along the bonding interface, and
a surface of each of the micro-wires is coplanar with the bonding surface.

2. The conductive film structure as claimed in claim 1, wherein the micro-wires comprise copper, nickel, cobalt, gold, tin, silver, lead, or alloys thereof.

3. The conductive film structure as claimed in claim 1, wherein the bonding interface comprises a spiroid interface or a folding interface.

4. The conductive film structure as claimed in claim 1, wherein the bonding interfaces are a plurality of planes parallel to each other.

5. The conductive film structure as claimed in claim 1, wherein cross-sectional areas of the micro-wires comprise shapes of a square, rectangle, half-circle, half-ellipse, trapezium, or polygon.

6. A conductive film type probe device for IC, comprising:
a circuit board having a plurality of first contacts and a plurality of second contacts, wherein the first contacts are used to electrically connect to a testing apparatus; and
a conductive film structure as claimed in claim 1, wherein each of the second contacts electrically connects to at least one of the micro-wires of the conductive film structure.

7. The conductive film type probe device for IC as claimed in claim 6, wherein the second contacts are arranged corresponding to, and in the same manner as contacts of a to-be-tested integrated circuit.
